(19) United States
(12) Patent Application Publication
(10) Pub. No.: US 2019/0056662 A1
(43) Pub. Date: Feb. 21, 2019

(54) COLORED RESIN COMPOSITION, COLOR FILTER SUBSTRATE AND LIQUID CRYSTAL DISPLAY DEVICE

(71) Applicant: Toray Industries, Inc., Tokyo (JP)

(72) Inventors: Shota Hashimoto, Otsu-shi,Shiga (JP); Tetsuo Yamashita, Otsu-shi,Shiga (JP); Yasuhiro Kamii, Otsu-shi, Shiga (JP); Kenichi Kawabe, Otsu-shi,Shiga (JP); Keizo Udagawa, Otsu-shi,Shiga (JP)

(73) Assignee: Toray Industries, Inc., Tokyo (JP)

(21) Appl. No.: 16/078,342

(22) PCT Filed: Mar. 17, 2017
(86) PCT No.: PCT/JP2017/010964

§ 371 Date: Aug. 21, 2018

(30) Foreign Application Priority Data
Mar. 25, 2016 (JP) 2016-061331

(51) Int. Cl. G03F 7/031; G03F 7/00; G02F 1/1335

(52) U.S. Cl. CPC G03F 7/031; G02F 2202/025; G02F 1/133514; G03F 7/0007

(57) ABSTRACT

Provided is a colored resin composition including a polyhalogenated zinc phthalocyanine, a yellow pigment, a binder resin, and a compound of the following general formula (1). The yellow pigment is a pigment selected from C.I. Pigment Yellow 138 and C.I. Pigment Yellow 185.

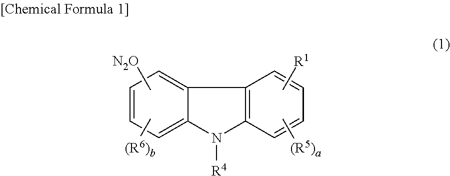

### CROSS REFERENCE TO RELATED APPLICATIONS

This is the U.S. National Phase application of PCT/JP2017/010964, filed Mar. 17, 2017, which claims priority to Japanese Patent Application No. 2016-061331, filed Mar. 25, 2016, the disclosures of these applications being incorporated herein by reference in their entireties for all purposes.

### TECHNICAL FIELD OF THE INVENTION

The present invention relates to a colored resin composition, a color filter substrate and a liquid crystal display device.

### BACKGROUND OF THE INVENTION

Liquid crystal display devices are used in various applications such as televisions, notebook personal computers, portable information terminals, smart phones and digital cameras owing to such characteristics that liquid crystal display devices are light and thin, and have low power consumption.

A liquid crystal display device is required to display optimum colors from three to six primary colors according to the use. An optimum color material has been sought as a coloring agent composition to be used for pixels of a color filter substrate contributing to the color performance of a liquid crystal display device.

In green pixels, combinations of various pigments have been examined, and generally a green pigment having a phthalocyanine skeleton and a yellow pigment are combined (Patent Document 1). Examples of the green pigment having a phthalocyanine skeleton include C.I. polyhalogenated copper phthalocyanines such as C.I. Pigment Green 36 (brominated copper phthalocyanine) and C.I. Pigment Green 7 (brominated and chlorinated copper phthalocyanine); and polyhalogenated zinc phthalocyanines such as C.I. Pigment Green 58 (brominated zinc phthalocyanine) and C.I. Pigment Green 59 (brominated and chlorinated zinc phthalocyanine) A green pigment having a phthalocyanine skeleton and a yellow pigment such as C.I. Pigment Yellow 138, C.I. Pigment Yellow 150, or C.I. Pigment Yellow 139 are used in combination. In addition, generally a plurality of yellow pigments are used in combination as yellow pigments (Patent Documents 2 and 3). Among various combinations, combinations of C.I. Pigment Green 58 and C.I. Pigment Yellow 138 are favorably used because they have a high initial transmittance (Patent Documents 2 and 3).

On the other hand, it is known that when phthalocyanine is irradiated with light while oxygen is blocked, the absorption spectrum is changed, resulting in a decrease in light transmittance of a green pixel formed of phthalocyanine (Non-Patent Document 1). That is, when a liquid crystal display device having a green pixel formed of phthalocyanine is irradiated with light while oxygen is blocked, the brightness of the liquid crystal display device is eliminated. Non-Patent Document 1 suggests that this phenomenon can be alleviated by modifying a phthalocyanine skeleton with a substituent. In addition, a technique is known in which a light stabilizer such as hindered amine is added for improving the light resistance of a color filter (Patent Document 4).

### Patent Documents

Patent Document 1: Japanese Patent Laid-open Publication No. 2014-41341
Patent Document 2: Japanese Patent Laid-open Publication No. 2015-169880
Patent Document 3: Japanese Patent Laid-open Publication No. 2012-141368
Patent Document 4: Japanese Patent Laid-open Publication No. 2011-102833

### Non-Patent Document

Non-Patent Document 1: Journal of Photopolymer Science and Technology Volume 7, Number I (1994) p. 151-158

### SUMMARY OF THE INVENTION

However, in conventional techniques, the effect of preventing a decrease in transmittance is insufficient. Thus, an object of the present invention is to provide a colored resin composition having a high transmittance retention ratio at the time when oxygen is blocked.

Specifically, the present invention provides a colored resin composition including a polyhalogenated zinc phthalocyanine, a yellow pigment, a binder resin, and a compound of the following general formula (1), the yellow pigment being a pigment selected from C.I. Pigment Yellow 138 and C.I. Pigment Yellow 185.

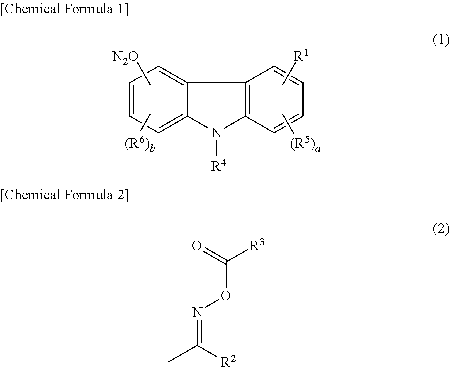

In the formula, R¹ represents a group selected from H, an alkyl group having 1 to 20 carbon atoms, an alkoxy group having 1 to 20 carbon atoms, an aryl group having 6 to 30 carbon atoms, an aryloxy group having 6 to 30 carbon atoms, an arylalkyl group having 7 to 30 carbon atoms, an arylalkyloxy group having 7 to 30 carbon atoms, a heterocyclic group having 2 to 20 carbon atoms, CN, a halogen atom and a group represented by the general formula (2).

R⁴ represents a group selected from an alkyl group having 1 to 20 carbon atoms, an aryl group having 6 to 30 carbon atoms and an arylalkyl group having 7 to 30 carbon atoms, and R⁴ may form a ring with an adjacent benzene ring.

R⁵ and R⁶ each independently represent an alkyl group having 1 to 20 carbon atoms, an alkoxy group having 1 to 20 carbon atoms, an aryl group having 6 to 30 carbon atoms, an aryloxy group having 6 to 30 carbon atoms, an arylalkyl group having 7 to 30 carbon atoms, an arylalkyl group having 7 to 30 carbon atoms, an arylalkyloxy group having 7 to 30 carbon atoms, a heterocyclic group having 2 to 20 carbon atoms, CN or a halogen atom, and a and b each independently represent 0 to 3.

R² represents a group selected from an alkyl group having 1 to 20 carbon atoms, an aryl group having 6 to 30 carbon atoms, an arylalkyl group having 7 to 30 carbon atoms, a heterocyclic group having 2 to 20 carbon atoms and CN, and

the alkyl group, the aryl group, the arylalkyl group and the heterocyclic group may be further substituted with OR²¹, COR²¹, SR²¹, NR²²R²³, —NCOR²²—OCOR²³, CN, a halogen atom, —CR²¹═CR²²R²³ or —CO—CR²¹═CR²²R²³.

R²¹, R²² and R²³ each independently represent a hydrogen atom, an alkyl group having 1 to 20 carbon atoms, an alkenyl group having 1 to 20 carbon atoms, an aryl group having 6 to 30 carbon atoms, an arylalkyl group having 7 to 30 carbon atoms, or a heterocyclic group of 2 to 20 carbon atoms.

R³ represents a group selected from an alkyl group having 1 to 20 carbon atoms, an alkoxy group having 1 to 20 carbon atoms, an aryl group having 6 to 30 carbon atoms, an aryloxy group having 6 to 30 carbon atoms, an arylalkyl group having 7 to 30 carbon atoms, an arylalkyl group having 7 to 30 carbon atoms, an arylalkyloxy group having 7 to 30 carbon atoms, and a heterocyclic group having 2 to 20 carbon atoms, and these groups may be further substituted with a halogen atom.

In the above description, the alkyl group may be a linear group or a group having a branched side chain, or a cyclic alkyl group, and the alkyl group may contain 1 to 5 bonds selected from unsaturated bonds, ether bonds, thioether bonds, ester bonds, thioester bonds, amide bonds and urethane bonds in the alkyl chain.

In addition, the present invention provides a color filter substrate having pixels formed using the colored resin composition.

In addition, the present invention provides a liquid crystal display device in which a color filter substrate and a counter substrate are bonded to each other, a liquid crystal compound is packed between both the substrates, and a backlight is provided, the color filter substrate having pixels containing a polyhalogenated zinc phthalocyanine, a yellow pigment, a binder resin and a compound represented by the general formula (1), the yellow pigment being at least one selected from the group consisting of C.I. Pigment Yellow 150, C.I. Pigment Yellow 138 and C.I. Pigment Yellow 185, the backlight having a luminance of 8000 to 100000 cd/m².

According to the present invention, it is possible to obtain a colored resin composition having a high initial transmittance, and a high transmittance retention ratio at the time when oxygen is blocked.

### DETAILED DESCRIPTION OF EMBODIMENTS OF THE INVENTION

The present inventors have extensively conducted studies on the above-described transmittance decrease phenomenon, and resultantly found that this phenomenon occurs in a phthalocyanine-based green pigment, and is particularly marked in a polyhalogenated zinc phthalocyanine (e.g. C.I. Pigment Green 58). In addition, it has been found that when a polyhalogenated zinc phthalocyanine is combined with a specific yellow pigment (e.g. C.I. Pigment Yellow 138), the transmittance markedly decreases. In addition, it has been found that this transmittance decrease phenomenon occurs when a colored resin composition is irradiated with light while oxygen is blocked, and the transmittance is recovered when the colored resin composition is opened to air, and exposed to an atmosphere containing oxygen after photoirradiation is completed. From the above-described findings, the present inventors have thought that this transmittance decrease phenomenon is a phenomenon caused by excitation of a phthalocyanine pigment, and the present inventors extensively conducted studies on a quencher for eliminating the excited state, and resultantly found that a compound represented by the following general formula (1) and having a nitrocarbazole skeleton is specifically effective as a quencher.

A general colored resin composition obtained by combining C.I. Pigment Green 58 and C.I. Pigment Yellow 138 has a high initial transmittance, but the transmittance markedly decreases when the colored resin composition is irradiated with light with ITO deposited on the colored resin composition. This is because the C.I. Pigment Green 58 excited by interaction with a specific yellow pigment as described above is kept in an excited state by blocking oxygen by the ITO film.

In the present invention, the transmittance is a Y value at x=0.265 and y=0.629 in a y-Y plot in an xy color space based on the CIE 1931 standard when a colored resin composition coating film is measured with a C light source using a microspectrometer. Details of the measurement method will be described below.

In the present invention, the colored resin composition contains a compound of the general formula (1), and thus the exited state of a polyhalogenated zinc phthalocyanine is eliminated, so that it is possible to prevent a decrease in transmittance due to photoirradiation at the time when oxygen is blocked.

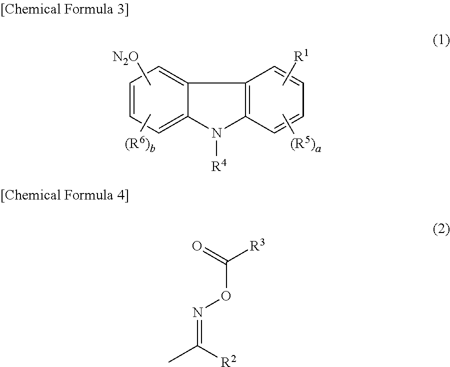

In the formula, R¹ represents a group selected from H, an alkyl group having 1 to 20 carbon atoms, an alkoxy group having 1 to 20 carbon atoms, an aryl group having 6 to 30 carbon atoms, an aryloxy group having 6 to 30 carbon atoms, an arylalkyl group having 7 to 30 carbon atoms, an arylalkyl group having 7 to 30 carbon atoms, an arylalkyloxy group having 7 to 30 carbon atoms, a heterocyclic group having 2 to 20 carbon atoms, CN, a halogen atom and a group represented by the general formula (2).

R⁴ represents a group selected from an alkyl group having 1 to 20 carbon atoms, an aryl group having 6 to 30 carbon atoms and an arylalkyl group having 7 to 30 carbon atoms, and R⁴ may be combined with an adjacent benzene ring to form a ring.

R⁵ and R⁶ each independently represent a group selected from an alkyl group having 1 to 20 carbon atoms, an alkoxy group having 1 to 20 carbon atoms, an aryl group having 6 to 30 carbon atoms, an aryloxy group having 6 to 30 carbon atoms, an arylalkyl group having 7 to 30 carbon atoms, an arylalkyl group having 7 to 30 carbon atoms, an arylalkyloxy group having 7 to 30 carbon atoms, a heterocyclic group having 2 to 20 carbon atoms, CN and a halogen atom, and a and b each independently represent 0 to 3.

R² represents a group selected from an alkyl group having 1 to 20 carbon atoms, an aryl group having 6 to 30 carbon atoms, an arylalkyl group having 7 to 30 carbon atoms, a heterocyclic group having 2 to 20 carbon atoms and CN, and the alkyl group, the aryl group, the arylalkyl group and the heterocyclic group may be further substituted with OR²¹, COR²¹, SR²¹, NR²²R²³, —NCOR²²—OCOR²³, CN, a halogen atom, —CR²¹═CR²²R²³ or —CO—CR²¹═CR²²R²³.

R²¹, R²² and R²³ each independently represent a hydrogen atom, an alkyl group having 1 to 20 carbon atoms, an alkenyl group having 1 to 20 carbon atoms, an aryl group having 6 to 30 carbon atoms, an arylalkyl group having 7 to 30 carbon atoms, or a heterocyclic group of 2 to 20 carbon atoms.

R³ represents a group selected from an alkyl group having 1 to 20 carbon atoms, an alkoxy group having 1 to 20 carbon atoms, an aryl group having 6 to 30 carbon atoms, an aryloxy group having 6 to 30 carbon atoms, an arylalkyl group having 7 to 30 carbon atoms, an arylalkyl group having 7 to 30 carbon atoms, an arylalkyloxy group having 7 to 30 carbon atoms, and a heterocyclic group having 2 to 20 carbon atoms, and these groups may be further substituted with a halogen atom.

In the above description, the alkyl group may be a linear group or a group having a branched side chain, or a cyclic alkyl group, and the alkyl group may contain 1 to 5 bonds selected from unsaturated bonds, ether bonds, thioether bonds, ester bonds, thioester bonds, amide bonds and urethane bonds in the alkyl chain.

The compound represented by the general formula (1) is a nitrocarbazole compound in which one benzene ring of a carbazole skeleton is substituted with a nitro group. The other benzene ring of the carbazole skeleton may be unsubstituted, or substituted with the substituents shown above. Examples of the compound include the following 9-ethyl-3-nitrocarbazole.

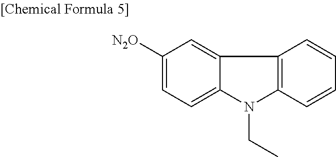

It is preferable that R¹ in the compound represented by the general formula (1) is a group represented by the general formula (2) because the compound functions not only as a quencher but also as a photopolymerization initiator. This compound itself is known, and described in Japanese Patent Publication No. 4223071, and the method for producing the compound is also described in this publication. A commercially available product may be used.

When this compound is used as a photopolymerization initiator, it is possible to sufficiently perform photocuring in exposure not only to an i-ray (365 nm) but also to light with a long wavelength, such as an h-ray (405 nm), and therefore it is possible to suit to an exposure system with a lower exposure amount, such as a lens scanning system.

The content of the compound represented by the general formula (1) is preferably 0.1 to 50% by mass, more preferably 2 to 20% by mass in the solid component. When the content of the compound is 0.1% by mass or less, the effect of improving the transmittance retention ratio is reduced. In addition, when the content of the compound is more than 50% by mass, the film may be brittle. Here, the “solid component” refers to the sum of components other than a solvent among components contained in the colored resin composition.

The colored resin composition of the present invention contains a colorant, a binder resin, and the compound of the above general formula (1).

The colorant includes a polyhalogenated zinc phthalocyanine, and a yellow pigment selected from C.I. Pigment Yellow 138 and C.I. Pigment Yellow 185 as essential components. C.I. Pigment Yellow 138 and C.I. Pigment Yellow 185 have a high initial transmittance. There has been the problem that the transmittance markedly decreases when C.I. Pigment Green 58 and C.I. Pigment Yellow 13.8 are used in combination as described above, but in the present invention, the problem of decrease in transmittance can be solved by including the compound represented by the general formula (1) as described above.

The content of the colorant is preferably in a range of 1 to 65% by mass, more preferably 10 to 55% by mass, still more preferably 10 to 50% by mass in the solid component. When the content of the colorant is lower than 1% by mass, coloring performance is deteriorated. In addition, when the content of the colorant is more than 65% by mass, the film may brittle.

The polyhalogenated zinc phthalocyanine is preferably at least one selected from C.I. Pigment Green 58 and C.I. Pigment Green 59.

From the viewpoint of color characteristics required for a color filter, the ratio of the polyhalogenated zinc phthalocyanine to the whole colorant is preferably 10 to 99% by mass where the total content of the colorant of the colored resin composition is 100%. The ratio of the polyhalogenated zinc phthalocyanine is more preferably 15% by mass or more, still more preferably 72% by mass or more. In addition, the ratio is more preferably 95% by mass or less. When the ratio of the polyhalogenated phthalocyanine increases, the concentration of the colorant is easily reduced to increase the amount of resin components, and so that the reliability of the resulting color filter is improved. The ratio of the yellow pigment to the whole colorant is preferably 1 to 90% by mass, more preferably 5 to 85% by mass.

C.I. Pigment Yellow 150 is also preferable as the yellow pigment. When C.I. Pigment Yellow 150 is further contained in addition to a pigment selected from C.I. Pigment Yellow 138 and C.I. Pigment Yellow 185, the transmittance retention ratio in a weather resistance test at the time of blocking oxygen can be further improved without significantly reducing the initial transmittance. Here, as a particularly favorable mixing ratio from the viewpoint of securing both the initial transmittance and the transmittance retention ratio, the total content of C.I. Pigment Yellow 138 and C.I. Pigment Yellow 185 is in a range of 20 to 85% by mass, more preferably in a range of 20 to 80% by mass where the total content of the yellow pigment is 100% by mass. In addition, the ratio of C.I. Pigment Yellow 150 is preferably in a range of 20 to 80% by mass in terms of the content of C.I. Pigment yellow 150 where the sum of the yellow pigment is 100% by mass.

When C.I. Pigment Yellow 138 is used as the yellow pigment, it is preferable from the viewpoint of easily increasing the luminance that the total content of the polyhalogenated zinc phthalocyanine and C.I. Pigment Yellow 138 is 43 to 55% by mass where the total of the polyhalogenated zinc phthalocyanine, C.I. Pigment Yellow 138, the binder resin, the reactive monomer and the dispersant is 100% by mass.

In addition, the colorant may contain other pigments as long as the properties are not impaired. For example, the colorant may contain C.I. Pigment Greens 1, 2, 4, 7, 8, 10, 13, 14, 15, 17, 18, 19, 26, 36, 45, 48, 50, 51, 54 or 55, or C.I. Pigment Yellows 1, 1:1, 2, 3, 4, 5, 6, 9, 10, 12, 13, 14, 16, 17, 24, 31, 32, 34, 35, 35:1, 36, 36:1, 37, 37:1, 40, 41, 42, 43, 48, 53, 55, 61, 62, 62:1, 63, 65, 73, 74, 75, 81, 83, 87, 93, 94, 95, 97, 100, 101, 104, 105, 108, 109, 110, 111, 116, 117, 119, 120, 126, 127, 127:1, 128, 129, 133, 134, 136, 139, 142, 147, 148, 151, 153, 154, 155, 157, 158, 159, 160, 161, 162, 163, 164, 165, 166, 167, 168, 169, 170, 172, 173, 174, 175, 176, 180, 181, 182, 183, 184, 188, 189, 190, 191, 191:1, 192, 193, 194, 195, 196, 197, 198, 199, 200, 202, 203, 204, 205, 206 or 207.

The binder resin is not particularly limited, and is preferably an acrylic resin, an epoxy resin, a polyimide resin, a urethane resin, a urea resin, a polyvinyl alcohol resin, a melamine resin, a polyamide resin, a polyamideimide resin, a polyester resin, a polyolefin resin or the like. From the viewpoint of stability, an acrylic resin is especially preferably used.

The acrylic resin is not particularly limited, but a copolymer of an unsaturated carboxylic acid and an ethylenically unsaturated compound can be preferably used. Examples of the unsaturated carboxylic acid include acrylic acid, methacrylic acid, itaconic acid, crotonic acid, maleic acid, fumaric acid, vinylacetic acid and acid anhydride.

These compounds may be used singly, or used in combination with other copolymerizable ethylenically unsaturated compounds. Specific examples of the copolymerizable ethylenically unsaturated compound include, but are not limited to, unsaturated carboxylic acid alkyl esters such as methyl acrylate, methyl methacrylate, ethyl acrylate, ethyl methacrylate, n-propyl acrylate, isopropyl acrylate, n-propyl methacrylate, isopropyl methacrylate, n-butyl acrylate, n-butyl methacrylate, sec-butyl acrylate, sec-butyl methacrylate, iso-butyl acrylate, iso-butyl methacrylate, tert-butyl acrylate, tert-butyl methacrylate, n-pentyl acrylate, n-pentyl methacrylate, 2-hydroxyethyl acrylate, 2-hydroxyethyl methacrylate, benzyl acrylate and benzyl methacrylate; aromatic vinyl compounds such as styrene, p-methylstyrene, o-methylstyrene, m-methylstyrene and α-methylstyrene; unsaturated carboxylic acid aminoalkyl esters such as aminoethyl acrylate; unsaturated carboxylic acid glycidyl esters such as glycidyl acrylate and glycidyl methacrylate; carboxylic acid vinyl esters such as vinyl acetate and vinyl propionate; vinyl cyanide compounds such as acrylonitrile, methacrylonitrile and α-chloroacrylonitrile; aliphatic conjugated dienes such as 1,3-butadiene and isoprene; and macromonomers, which has a acryloyl group or a methacryloyl group at the end, such as polystyrenes, polymethyl acrylate, polymethyl methacrylate, polybutyl acrylate, polybutyl methacrylate and polysilicone.

In addition, use of an acrylic resin with an ethylenically unsaturated group added to a side chain is preferable because the sensitivity in processing is improved when the colored resin composition is used as a photosensitive resin composition. Examples of the ethylenically unsaturated group include a vinyl group, an allyl group, an acryl group and a methacryl group. As a method for adding the side chain to an acryl-based (co)polymer, a method is generally employed in which when the acrylic resin has carboxyl groups, hydroxyl groups or the like, these groups are subjected to an addition reaction with an ethylenically unsaturated compound having an epoxy group, acrylic acid chloride, methacrylic acid chloride or the like. In addition, it is also possible to add a compound having an ethylenically unsaturated group using an isocyanate.

An acrylic resin which is produced by such a method and which has an unsaturated group in the side chain can be further purified by an ion-exchange method or reprecipitation. Examples of the method for reprecipitation include a method in which the binder resin solution is mixed with water or various organic solvents, and the resin is thus precipitated to obtain a powder.

As the acrylic resin having an ethylenically unsaturated group in the side chain, for example, Cyclomer (registered trademark) P (Daicel Chemical Industries, Ltd.), which is a commercially available acrylic resin, or an alkali-soluble cardo resin can be used.

The mass average molecular weight Mw of the binder resin is preferably 3,000 to 200,000, more preferably 9,000 to 100,000. When the mass average molecular weight is less than 3,000, the strength of the resulting cured film is reduced. On the other hand, it is not preferable that the mass average molecular weight is more than 200,000 because the stability of the resin composition is deteriorated. Here, the mass average molecular weight Mw is a value obtained by performing measurement by gel permeation chromatography, and converting the measured value using a calibration curve prepared with standard polystyrene.

The content of the binder resin is preferably 1 to 99% by mass, more preferably 5 to 95% by mass in the solid component from the viewpoint of balance between developability and color characteristics.

The resin composition of the present invention may contain other additives. Examples of other additives include organic solvents, adhesion improvers and surfactants.

Examples of the organic solvent when an acrylic resin is used as the binder resin include diethylene glycol monobutyl ether acetate (boiling point: 247° C.), benzyl acetate (boiling point: 214° C.), ethyl benzoate (boiling point: 213° C.), methyl benzoate (boiling point: 200° C.), diethyl malonate (boiling point: 199° C.), 2-ethylhexyl acetate (boiling point: 199° C.), 2-butoxyethyl acetate (boiling point: 192° C.), ethylene glycol monobutyl ether acetate (boiling point: 188° C.), diethyl oxalate (boiling point: 185° C.), ethyl acetoacetate (boiling point: 181° C.), cyclohexyl acetate (boiling point: 174° C.), 3-methoxybutyl acetate (boiling point: 173° C.), methyl acetoacetate (boiling point: 172° C.), ethyl 3-ethoxypropionate (boiling point: 170° C.), 2-ethylbutyl acetate (boiling point: 162° C.), isopentyl propionate (boiling point: 160° C.), propylene glycol monomethyl ether propionate (boiling point 160° C.), pentyl acetate (boiling point: 150° C.) and propylene glycol monomethyl ether acetate (boiling point: 146° C.; hereinafter, referred to as “PMA”).

In addition, examples of the solvent other than the above-mentioned solvents include (poly)alkylene glycol ether-based solvents such as ethylene glycol monomethyl ether (boiling point: 124° C.), ethylene glycol monoethyl ether (boiling point: 135° C.), propylene glycol monoethyl ether (boiling point: 133° C.), diethylene glycol monomethyl ether (boiling point: 193° C.), monoethyl ether (boiling point: 135° C.), methyl carbitol (boiling point: 194° C.), ethyl carbitol (boiling point: 202° C.), propylene glycol monomethyl ether (boiling point: 120° C.), propylene glycol monoethyl ether (boiling point 133° C.), propylene glycol tertiary-butyl ether (boiling point 153° C.) and dipropylene glycol monomethyl ether (boiling point 188° C.); aliphatic esters such as ethyl acetate (boiling point: 77° C.), butyl acetate (boiling point: 126° C.) and isopentyl acetate (boiling point: 142° C.); aliphatic alcohols such as butanol (boiling point: 118° C.), 3-methyl-2-butanol (boiling point: 112° C.) and 3-methyl-3-methoxybutanol (boiling point: 174° C.); ketones such as cyclopentanone and cyclohexanone; and xylene (boiling point 144° C.), ethylbenzene (boiling point: 136° C.) and solvent naphtha (petroleum fraction: boiling point: 165 to 178° C.).

From the viewpoint of balance between coating property and the drying property, the content of the organic solvent is preferably 40 to 95% by mass, more preferably 50 to 90% by mass based on the total amount of the colored resin composition.

The adhesion improver can be preferably added for the purpose of improving adhesion of the coating film to the substrate. Examples of the adhesion improver include silane coupling agents such as vinyltrimethoxysilane, vinyltriethoxysilane, vinyltris(2-methoxyethoxy)silane, N-(2-aminoethyl)-3-aminopropylmethyldimethoxysilane, N-(2-aminoethyl)-3-aminopropyltrimethoxysilane, 3-aminopropyltriethoxysilane, 3-glycidoxypropyltrimethoxysilane, 3-glycidoxypropylmethyldimethoxysilane, 2-(3,4-epoxycyclohexyl)ethyltrimethoxysilane, 3-chloropropylmethyldimethoxysilane, 3-chloropropyltrimethoxysilane, 3-methacryloxypropyltrimethoxysilane, and 3-mercaptopropyltrimethoxysilane.

From the viewpoint of balance between adhesion and compatibility with the binder resin, the content of the adhesion improver is preferably 10% by mass or less, more preferably 5% by mass or less in the solid component.

The surfactant can be added for the purpose of improving the coatability of the resin composition and the uniformity of the surface of the layer. Specific examples of the surfactant include anionic surfactants such as ammonium lauryl sulfate and polyoxyethylenealkyl ether sulfuric acid triethanol amines; cationic surfactants such as stearylamine acetate and lauryltrimethylammonium chloride; amphoteric surfactants such as lauryldimethylamine oxide and laurylcarboxymethylhydroxyethyl imidazolium betaine; nonionic surfactants such as polyoxyethylene lauryl ether, polyoxyethylene stearyl ether and sorbitan monostearate; fluorine-based surfactants; and silicon-based surfactants. The addition amount of the surfactant is preferably 0.001 to 10% by mass based on the total amount. When the addition amount is below the above-mentioned range, the effect of improving coatability and uniformity of the film surface is low, and it is not preferable that the addition amount is excessively large because coatability is deteriorated.

The colored resin composition according to the present invention can be used either as a photosensitive resin composition or as a non-photosensitive resin composition. When the colored resin composition is used as a photosensitive resin composition, it is preferable that the colored resin composition further contains a reactive monomer and a photopolymerization initiator.

The reactive monomer is not particularly limited, but a polyfunctional (meth)acrylate is preferably used. Examples of the polyfunctional (meth)acrylate that can be used include oligomers such as bisphenol A diglycidyl ether (meth)acrylate, poly(meth)acrylate carbamate, modified bisphenol A epoxy (meth)acrylate, adipic acid 1,6-hexanediol (meth)acrylic acid esters, phthalic anhydride propylene oxide (meth)acrylic acid esters, trimellitic acid diethylene glycol (meth)acrylic acid esters, rosin-modified epoxy di(meth)acrylate and alkyd-modified (meth)acrylate; tripropylene glycol di(meth)acrylate, 1,6-hexanediol di(meth)acrylate, bisphenol A diglycidyl ether di(meth)acrylate, trimethylolpropane tri(meth)acrylate, tetratrimethylolpropane tri(meth)acrylate, pentaerythritol tri(meth)acrylate, triacrylformal, pentaerythritol tetra(meth)acrylate, dipentaerythritol hexa(meth)acrylate, dipentaerythritol penta(meth)acrylate, bisphenoxyethanolfluorene diacrylate and dicyclopentanedienyl diacrylate; or alkyl-modified products, alkylether-modified products, or alkylester-modified products thereof. These reactive monomers may be used singly, or used in combination of two or more thereof.

When R¹ in the compound represented by the general formula (1) is a group represented by the general formula (2), the compound functions not only as a quencher but also as a photopolymerization initiator as described above. Examples of the photopolymerization initiator represented by the general formula (1) include ADEKA ARKLS (registered trademark) NCI-831 manufactured by ADEKA Corporation. In addition, a photopolymerization initiator other than the compound represented by the general formula (1) can be added.

Examples of other photopolymerization initiators include benzophenone-based compounds, acetophenone-based compounds, imidazole-based compounds, benzothiazole-based compounds, benzoxazole-based compounds, oxime ester-based compounds, triazine-based compounds, and inorganic photopolymerization initiators such as phosphorus-based compounds and titanate.

More specific examples thereof include benzophenone, N,N′-tetraethyl-4,4′-diaminobenzophenone, 4-methoxy-4′-dimethylaminobenzophenone, 2,2-diethoxyacetophenone, benzoin, benzoin methyl ether, benzoin isobutyl ether, benzyl dimethyl ketal, α-hydroxyisobutylphenone, 1-hydroxycyclohexyl phenyl ketone, 2-methyl-1-[4-(methylthio)phenyl]-2-morpholino-1-propane, IRGACURE (registered trademark) 369 (2-benzyl-2-dimethylamino-1-(4-morpholinophenyl)-butanone), IRGACURE 379 (2-(dimethylamino)-2-[(4-methylphenyl)methyl]-1-[4-(4-morpholinyl)phenyl]-1-butanone) and IRGACURE OXE 01 (1,2-octanedione, 1-[4-(phenylthio)-2-(O-benzoyloxime)]) which are each manufactured by Ciba Specialty Chemicals Ltd, t-butyl anthraquinone, 1-chloroanthraquinone, 2,3-dichloroanthraquinone, 3-chloro-2-methylanthraquinone, 2-ethylanthraquinone, 1,4-naphthoquinone, 9,10-phenanthraquinone, 1,2-benzoanthraquinone, 1,4-dimethylanthraquinone, 2-phenylanthraquinone, 2-(o-chlorophenyl)-4,5-diphenylimidazole dimers, 2-mercaptobenzothiazole, 2-mercaptobenzoxazole, 4-(p-methoxyphenyl)-2,6-di-(trichloromethyl)-s-triazine, and ADEKA ARKLS (registered trademark) NCI-930 as an oxime ester-based compound.

In addition, it is preferable to use a chain transfer agent together with the photopolymerization initiator for the purpose of improving the sensitivity. Examples of the chain transfer agent include mercapto compounds such as thioglycolic acid, thiomalic acid, thiosalicylic acid, 2-mercaptopropionic acid, 3-mercaptopropionic acid, 3-mercaptobutyric acid, N-(2-mercaptopropionyl)glycine, 2-mercaptonicotinic acid, 3-[N-(2-mercaptoethyl)carbamoyl]propionic acid, 3-[N-(2-mercaptoethyl)amino]propionic acid, N-(3-mercaptopropionyl)alanine, 2-mercaptoethanesulfonic acid, 3-mercaptopropanesulfonic acid, 4-mercaptobutanesulfonic acid, dodecyl(4-methylthio)phenyl ether, 2-mercaptoethanol, 3-mercapto-1,2-propanediol, 1-mercapto-2-propanol, 3-mercapto-2-butanol, mercaptophenol, 2-mercaptoethylamine, 2-mercaptoimidazole, 2-mercapto-3-pyridinol, 2-mercaptobenzothiazole, mercaptoacetic acid, trimethylolpropane tris(3-mercaptopropionate), KARENZ (registered trademark) MT PE-1 (pentaerythritol tetrakis(3-mercaptopropionate)) manufactured by Showa Denko K.K., KARENZ (registered trademark) MT NR-1 (1,3,5 tris(3-mercaptobutyloxyethyl)-1,3,5-triazine-2,4,6(1H,3H,5H)-trione) manufactured by Showa Denko K.K., and KARENZ (registered trademark) MT BD-1 (1,4-bis(3-mercaptobutyryloxy)butane), manufactured by Showa Denko K.K.; disulfide compounds obtained by oxidizing the mercapto compounds; and iodinated alkyl compounds such as iodoacetic acid, iodopropionic acid, 2-iodoethanol, 2-iodoethanesulfonic acid and 3-iodopropanesulfonic acid.

From the viewpoint of balance between the sensitivity and compatibility with the binder resin, the content of the chain transfer agent is preferably 0.01 to 10% by mass, more preferably 0.1 to 3% by mass in the solid component.

When a sensitizer is further added, the sensitivity can be further improved. Examples of the sensitizer include thioxanthone-based sensitizers and aromatic or aliphatic tertiary amines. More specific examples thereof include thioxanthone, 2-chlorothioxanthone, and DETX-S (2,4-diethylthioxanthene-9-one).

In addition, two or more of these sensitizers may be used in combination. The addition amount of the sensitizer is not particularly limited, and is preferably 2 to 30% by mass, more preferably 5 to 25% by mass based on the total solid component of the photosensitive composition.

A polymerization inhibitor may be added to the resin composition for maintaining stability. Examples of the polymerization inhibitor include, but are not particularly limited to, hydroquinone, tert-butylhydroquinone, 2,5-bis (1,1,3,3-tetramethylbutyl)hydroquinone, 2,5-bis-(1,1-dimethylbutyl)hydroquinone, catechol and tert-butyl catechol.

From the viewpoint of balance between stability and photosensitive property, the content of the polymerization inhibitor is preferably in a range of 0.0001 to 1% by mass, more preferably 0.005 to 0.5% by mass in the solid component.

A method for producing a colored resin composition will now be described. Preferably, the colored resin composition is produced by dispersing a pigment, a binder resin and a solvent by a disperser to prepare a pigment dispersion liquid, and then adding other constituent components. Examples of the disperser include sand mills, ball mills, bead mills, three-roll mills and attritors. A bead mill which is excellent in dispersion efficiency is preferable. Examples of dispersing beads to be used in the bead mill include zirconia beads, alumina beads and glass beads, with zirconia beads being preferable.

For improving the dispersion stability of pigments, it is preferable to add a dispersant in preparation of the pigment dispersion liquid. As the dispersant, a pigment derivatives, a polymer dispersant or the like can be used. Examples of the pigment derivative may include pigment skeleton alkylamine modified products, carboxylic acid derivatives and sulfonic acid derivatives. The pigment derivative is effective as a synergist for wetting a pigment and stabilizing a fine pigment. Among the above-mentioned pigment derivatives, sulfonic acid derivatives of organic pigments have a high effect of stabilizing fine pigments, and are preferably used. The polymer dispersant is not particularly limited as long as it is used for a color filter, and various materials such as polymers such as polyester, polyalkylamines, polyallylamines, polyimine, polyamide, polyurethane, polyacrylate, polyimide and polyamideimide or copolymers thereof can be used singly or in combination. Among the above-mentioned polymer dispersants, those having an amine value and an acid value are preferable. Specifically, the polymer dispersant is preferably one having an amine value of 5 to 200 in terms of a solid content, and an acid value of 1 to 100. Use of these dispersants is preferable because the storage stability of the pigment dispersion liquid and hence of the colored resin composition is improved.

After preparation of the pigment dispersion liquid by such a method, a diluted varnish obtained by mixing an acryl-based resin, a reactive monomer, a photopolymerization initiator, a polymerization inhibitor, other additives and so on according to a target composition is prepared, and mixed with the pigment dispersion liquid to obtain a colored resin composition.

A color filter substrate obtained using the photosensitive colorant composition according to the present invention will now be described. In the color filter substrate according to the present invention, it is necessary to form colored pixels of at least one color using the colored resin composition according to the present invention. Except for the above, the configuration of the color filter is not particularly limited, and for example, a color filter obtained by forming red, green and blue pixels after forming a resin black matrix on a transparent substrate is preferably used.

The pigment to be used for the resin black matrix is not particularly limited as long as it plays a role as a light shielding agent. Pigment Black 7 as an organic pigment, carbon black, graphite, iron oxide, manganese oxide, titanium black or the like is used as a light shielding agent. It is also preferable to subject the pigment to a surface treatment. In addition, if necessary, a plurality of light shielding agents can be used in combination, or pigments of other colors can be added.

The pigment used for red pixels is not particularly limited as long as it plays a role. Examples of the red pigment to be used include Pigment Reds 9, 48, 97, 122, 123, 144, 149, 166, 168, 177, 179, 180, 192, 209, 215, 216, 217, 220, 223, 224, 226, 227, 228, 240 and 254. Examples of the yellow pigment to be used include Pigment Yellows 12, 13, 17, 20, 24, 83, 86, 93, 95, 109, 110, 117, 125, 129, 137, 138, 139, 147, 148, 150, 153, 154, 166, 168 and 185. Examples of the orange pigment include Pigment Oranges 13, 36, 38, 43, 51, 55, 59, 61, 64, 65 and 71.

The pigment used for blue pixels is not particularly limited as long as it plays a role. Examples of the blue pigment to be used include Pigment Blues 15, 15:3, 15:4, 15:6, 22, 60 and 64. Pigment Violets 19, 23, 29, 30, 32, 37, 40, 50 and the like are used.

For green pixels, the colored resin composition according to the present invention is suitably used.

A method for producing a color filter substrate when the colored resin composition is photosensitive will now be described.

First, a colored resin composition is applied onto a substrate. Examples of the coating method that can be used include various methods such as a method in which a colored resin composition is applied to a substrate by using a spin coater, a bar coater, a blade coater, a roll coater, a die coater, an inkjet printing method, a screen printing method or the like; a method in which a substrate is immersed in a colored resin composition; and a method in which a colored resin composition is sprayed to a substrate.

As the substrate, a transparent substrate of soda glass, alkali-free glass, borosilicate glass, quartz glass or the like is preferably used. After the colored resin composition is applied onto the transparent substrate by a method as described above, a coating film of the colored resin composition is formed by air drying, heating and drying, vacuum drying or the like.

Next, using an ultra-high-pressure mercury lamp, a chemical lamp, a high-pressure mercury lamp or the like, the coating film of the colored resin composition is selectively exposed to ultraviolet light or the like with a mask placed on the coating film. The exposure machine can be used in any of proximity, mirror projection, lens scanning and the like. From the viewpoint of accuracy, a lens scanning method is preferable.

Thereafter, development with an alkaline developer is performed. Examples of the alkaline substance to be used in the alkaline developer include inorganic alkalis such as sodium hydroxide, potassium hydroxide, sodium carbonate, potassium carbonate, sodium silicate, sodium metasilicate and ammonia water; primary amines such as ethylamine and n-propylamine; secondary amines such as diethylamine and di-n-propylamine; tertiary amines such as triethylamine and methyldiethylamine; and organic alkalis such as tetramethylammonium hydroxide.

Thereafter, the resulting coating film pattern is subjected to a heating treatment to form a color filter substrate on which pixels are patterned. Normally, the heat treatment is performed continuously or stepwise in air, a nitrogen atmosphere, vacuum or the like at a temperature of 150 to 350° C., preferably 180 to 250° C., for 0.5 to 5 hours. Through this heating step, curing of the resin component of the photosensitive colorant composition proceeds. A patterning step is sequentially carried out for the black matrix and each of pixels of three to six primary colors.

If necessary, an overcoat film may be formed thereon. Examples of the overcoat film include epoxy films, acrylic epoxy films, acrylic films, siloxane polymer-based films, polyimide films, silicon-containing polyimide films and polyimide siloxane films. A transparent conductive film may be further formed on the overcoat film.

Examples of the transparent conductive film include metal oxide thin films of ITO or the like with a thickness of about 0.1 μm. Examples of the method for preparing an ITO film include a sputtering method and a vacuum vapor deposition method.

A fixed spacer may be formed on the color filter substrate. The fixed spacer is one that is fixed at a specific location on the color filter substrate, and is in contact with the counter substrate when a liquid crystal display device is prepared. Accordingly, a certain gap is held between the color filter substrate and the counter substrate, and a liquid crystal compound is packed in the gap. By forming a spacer fixed to the color filter substrate, the step of spreading a spherical spacer in the process for producing a liquid crystal display device, and the step of mixing and kneading a rod-shaped spacer in a sealing agent can be omitted.

The liquid crystal display device will now be described. The liquid crystal display device can be produced by bonding a color filter substrate and a counter substrate to each other, and packing a liquid crystal compound in a gap between both the substrates. As the counter substrate, for example, a counter substrate can be used in which a liquid crystal alignment film subjected to a rubbing treatment for liquid crystal alignment is provided on a driving element substrate having a thin-film diode (TFD) element, a scanning line, a signal line and a transparent electrode. The color filter substrate is also subjected to a rubbing treatment for liquid crystal orientation. The counter substrate and the color filter substrate are opposed to each other, and bonded to each other using a sealing material. Next, a liquid crystal is injected from an injection port provided at a seal part, the injection port is then sealed, a backlight is attached, an IC driver or the like is mounted to completely form a liquid crystal display device. As a backlight, for example, a white LED including a blue LED and a YAG phosphor can be used.

The color filter substrate has pixels containing a polyhalogenated zinc phthalocyanine, a yellow pigment, a binder resin, and a compound represented by the general formula (1), the yellow pigment being at least one selected from the group consisting of C.I. Pigment Yellow 150, C.I. Pigment Yellow 138 and C.I. Pigment Yellow 185.

The luminance of the backlight is preferably 8000 to 100000 cd/m², more preferably from 10000 to 50000 cd/m², still more preferably from 15000 to 30000 cd/m². Preferably, the backlight has a high luminous intensity because the visibility of the liquid crystal display device is improved. A transmittance decrease phenomenon that is a disadvantage of conventional techniques is proportional to a luminance, and the transmittance markedly decreases when the luminance of the backlight is 8000 cd/m² or more. However, when the colored resin composition according to the present invention is used, the transmittance decrease phenomenon can be prevented, and therefore the visibility of the liquid crystal display device can be improved by setting the luminance of the backlight to 8000 cd/m² or more. From the viewpoint of the visibility of the liquid crystal display device, the luminance of the backlight is preferably as high as possible, but when the luminance is more than 100000 cd/m², the panel cooling cost increases.

As a method for analyzing the colored resin composition, the colored resin composition can be analyzed by the following analysis method after the colored resin composition is applied onto a substrate, and dried. The analysis of pigment can be measured using a laser Raman (e.g. Ramanor T-64000 manufactured by HOLIBA Jobin Yvon GmbH.). The quencher, chain transfer agent, sensitizer and the like can be analyzed using FT-IR (e.g. FT-IR MICROSCOPE manufactured by SPECTR-TECH Inc.). In addition, detection can be performed with high accuracy by combining collection methods such as centrifugal separation, filtration and GPC preparative isolation, or combining a plurality of the above-mentioned analysis methods if necessary.

In addition, a method for analyzing the colored resin composition using the color filter substrate can be carried out in the same manner as described above after a transparent electrode layer and a protective film layer of the color filter substrate are removed by surface polishing to expose the colored resin composition, and analysis sample is collected by a manipulator.

### EXAMPLES

Hereinafter, the present invention will be described more in detail by way of preferred embodiments.

Evaluation of the colored resin composition in examples was performed by the following method.

<Evaluation Method>

(Evaluation of Initial Transmittance)

A colored resin composition was applied onto a glass substrate, dried at 90° C. for 10 minutes, exposed to an i-ray over the whole surface with an exposure amount of 40 mJ/cm², and then heated at 230° C. for 30 minutes. The thicknesses of green pixels formed in examples and comparative examples described below are shown in Table 2. The obtained colored resin composition coating film was measured with a C light source using a microspectrometer “LCF-100 MA” manufactured by Otsuka Electronics Co., Ltd., a Y value at x=0.265 and y=0.629 was determined in a y-Y plot in an xy color space based on the CIE 1931 standard, and the Y value was defined as an initial transmittance. Evaluation was performed in accordance with the following criteria.

A: initial transmittance is 51 or more
B: initial transmittance is more than 49 and less than 51
C: initial transmittance is 49 or less

(Evaluation of Transmittance Retention Ratio)

(1) Preparation of Color Filter

On a glass substrate with a black matrix formed thereon, green pixels were formed in the following manner using a colored resin composition according to the present invention.

For a non-photosensitive colored resin composition, the colored resin composition was applied onto the substrate, and then heated and dried at 90° C. for 10 minutes. A positive resist was applied to the obtained colored resin composition coating film, and heated and dried at 90° C. for 10 minutes. Subsequently, the film was exposed with an amount of 100 mJ/cm² through a positive photomask, and development was then performed with a 1.0 mass % tetramethylammonium solution to form a desired pattern. The positive resist was peeled off with methyl cellosolve acetate, and the film was then heated and cured at 230° C. for 30 minutes.

For a photosensitive colored resin composition, the colored resin composition was applied onto the substrate, and then heated and dried at 90° C. for 10 minutes. Subsequently, the colored resin composition coating film was exposed with an amount of 100 mJ through a negative photomask, and development was then performed with a 0.3 mass % tetramethylammonium solution to form a desired pattern. Subsequently, the film was heated and cured at 230° C. for 30 minutes.

Next, using a red resin composition and a blue resin composition, red pixels and blue pixels were formed on the substrate in the same manner as described above. Thereafter, a transparent electrode was formed to obtain a color filter substrate having green pixels, blue pixels and red pixels. The transmittance of the green pixels of the color filter substrate was measured by microspectrometry in the same manner as described above (evaluation of initial transmittance), and the obtained Y value was defined as Y0.

(2) Preparation of Liquid Crystal Display Device

A TFT element, a transparent electrode and the like were formed on an alkali-free glass to prepare an array substrate. A polyimide alignment film was formed on each of the color filter substrate prepared in (1) and the array substrate, and subjected to a rubbing treatment. A sealing agent containing micro-rods was applied to the array substrate, a 6 μm-thick bead spacer was spread, and the array substrate and the color filter substrate were then bonded to each other. A nematic liquid crystal (“LIXON” JC-5007LA manufactured by CHISSO CORPORATION) was injected from an injection port provided at a seal part, and a polarizing film was then bonded to each of both surfaces of a liquid crystal cell in such a manner that the polarizing axis was perpendicular, thereby obtaining a liquid crystal panel. A white LED backlight including a blue LED and a YAG phosphor was attached to the liquid crystal panel, and a TAB module, a printed circuit board and the like were mounted to prepare a liquid crystal display device. In the white LED backlight that was used, the driving power was adjusted, and the luminance was 5000 to 20000 cd/m².

(3) Weather Resistance Test

The liquid crystal display device was placed in a constant-temperature and high-humidity bath at a temperature of 60° C. and a humidity of 60% for 100 hours while the backlight was lit. Thereafter, the panel was disassembled, green pixels were measured by microspectrometry in the same manner as described above, and the obtained Y value was defined as Y1. Y1/Y0 was defined as a transmittance retention ratio, and evaluation was performed in accordance with the following criteria.

A: transmittance retention ratio is 90% or more
B: transmittance retention ratio is 80% or more and less than 90%
C: transmittance retention ratio is less than 80%

(Evaluation of Photosensitive Property)

A colored resin composition was applied onto a glass substrate, dried at 90° C. for 10 minutes, and exposed to ultraviolet light through a photomask having a 50 μm line & space pattern with an exposure time adjusted so that the exposure amount was 10, 20, 30, 40, 50, 100, 200 or 400 mJ/cm² in terms of an i-ray. There was a gap of 25 μm between the substrate and the photomask.

Next, the exposed substrate was subjected to shower development in a 0.2 mass % tetramethylammonium hydroxide aqueous solution at 23° C. for 60 seconds, and then washed with pure water. Heating was performed at 230° C. for 30 minutes.

Separately, a colored resin composition was applied onto a glass substrate under the same conditions as described above, exposed over the whole surface with an exposure amount of 400 mJ/cm² in terms of an i-ray, and then heated at 230° C. for 30 minutes without performing development.

For the substrate after the pattern processing, the thickness of the 50 μm line pattern was measured. Where the thickness of the colored resin composition film of a substrate that was not subjected to development was 100%, the exposure amount with which 90% or more of the thickness was retained was determined. The thickness was measured by “Surface Texture and Contour Measuring Instrument SURFCOM (registered trademark) 1400” manufactured by TOKYO SEIMITSU CO., LTD. Of the above-mentioned exposure amounts, the smallest exposure amount with which 90% or more of the thickness was retained was defined as a sensitivity. Evaluation was performed in accordance with the following criteria.

A: sensitivity is 30 mJ/cm² or less
B: sensitivity is more than 30 mJ/cm² and 400 mJ/cm² or less
C: sensitivity is more than 400 mJ/cm²
No photosensitivity: not evaluated

(Preparation of Colorant Dispersion Liquid)

Mixed were 150 g of C.I. Pigment Green 58 (“FASTGEN (registered trademark) Green A110” manufactured by DIC Corporation), 75 g of a polymer dispersant (“BYK-LPN 6919” manufactured by BYK Additives & Instruments; 60 mass % solution), 100 g of a binder polymer (“Cyclomer (registered trademark) P” manufactured by Daicel Chemical Industries, Ltd.; ACA 250; 45 mass % solution) and 675 g of propylene glycol monomethyl ether (PMA) to prepare a slurry. The beaker containing the slurry was connected to a Dyno-mill with a tube, and using zirconia beads having a diameter of 0.5 mm as a medium, a dispersion treatment was performed at a peripheral speed of 14 m/s for 8 hours to prepare a Pigment Green 58 dispersion liquid (D-1).

Mixed were 150 g of C.I. Pigment Yellow 138 (“LIONOGEN (registered trademark) YELLOW 1010” manufactured by Toyo Ink Co., Ltd.), 75 g of a polymer dispersant (“BYK-LPN 6919” manufactured by BYK Additives & Instruments; 60 mass % solution), 100 g of a binder polymer (“Cyclomer (registered trademark) P” manufactured by Daicel Chemical Industries, Ltd.; ACA 250; 45 mass % solution) and 675 g of propylene glycol monomethyl ether (PMA) to prepare a slurry. The beaker containing the slurry was connected to a Dyno-mill with a tube, and using zirconia beads having a diameter of 0.5 mm as a medium, a dispersion treatment was performed at a peripheral speed of 14 m/s for 8 hours to prepare a Pigment Yellow 138 dispersion liquid (D-2).

Mixed were 150 g of C.I. Pigment Yellow 150 (“CHROMOFINE (registered trademark) Yellow 6266 EC” manufactured by Dainichiseika Color & Chemicals Mfg. Co., Ltd.), 75 g of a polymer dispersant (“BYK-LPN 6919” manufactured by BYK Additives & Instruments; 60 mass % solution), 100 g of a binder polymer (“Cyclomer (registered trademark) P” manufactured by Daicel Chemical Industries, Ltd.; ACA 250; 45 mass % solution) and 675 g of propylene glycol monomethyl ether (PMA) to prepare a slurry. The beaker containing the slurry was connected to a Dyno-mill with a tube, and using zirconia beads having a diameter of 0.5 mm as a medium, a dispersion treatment was performed at a peripheral speed of 14 m/s for 8 hours to prepare a Pigment Yellow 150 dispersion liquid (D-3).

Mixed were 150 g of C.I. Pigment Green 59, 75 g of a polymer dispersant (“BYK-LPN 6919” manufactured by BYK Additives & Instruments; 60 mass % solution), 100 g of a binder polymer (“Cyclomer (registered trademark) P” manufactured by Daicel Chemical Industries, Ltd.; ACA 250; 45 mass % solution) and 675 g of propylene glycol monomethyl ether (PMA) to prepare a slurry. The beaker containing the slurry was connected to a Dyno-mill with a tube, and using zirconia beads having a diameter of 0.5 mm as a medium, a dispersion treatment was performed at a peripheral speed of 14 m/s for 8 hours to prepare a Pigment Green 59 dispersion liquid (D-4).

Mixed were 150 g of C.I. Pigment Yellow 185 (“Paliotol (registered trademark) Yellow D1155” manufactured by BASF SE), 75 g of a polymer dispersant (“BYK-LPN 6919” manufactured by BYK Additives & Instruments; 60 mass % solution), 100 g of a binder polymer (“Cyclomer (registered trademark) P” manufactured by Daicel Chemical Industries, Ltd.; ACA 250; 45 mass % solution) and 675 g of propylene glycol monomethyl ether (PMA) were mixed to prepare a slurry. The beaker containing the slurry was connected to a Dyno-mill with a tube, and using zirconia beads having a diameter of 0.5 mm as a medium, a dispersion treatment was performed at a peripheral speed of 14 m/s for 8 hours to prepare a Pigment Yellow 185 dispersion liquid (D-5).

### Example 1

(Preparation of Colored Resin Composition)

Added were 36.84 g of D-1, 24.56 g of D-2, 1.51 g of Cyclomer (registered trademark) P, 4.59 g of a DPHA (dipentaerythritol hexaacrylate) reactive monomer (“KAYARAD (registered trademark) DPHA” manufactured by Nippon Kayaku Co., Ltd., 0.29 g of a quencher (“9-ethyl-3-nitrocarbazole” (purity 98%) manufactured by Sigma-Aldrich Co. LLC)) and 32.21 g of PMA to prepare a colored resin composition of C.I. Pigment Green 58/C.I. Pigment Yellow 138 (60/40).

The obtained colored resin composition was evaluated in accordance with the above-described evaluation method with a backlight luminance of 10000 cd/m². The colored resin composition had a favorable initial transmittance of 51.0. Further, weather resistance was evaluated, and the result showed that the colored resin composition had a favorable transmittance retention ratio of 84%.

### Example 2

Except that 9-ethyl-3-nitrocarbazole as a quencher in Example 1 was replaced by a nitrocarbazole-based initiator of the following formula (3), exactly the same procedure as in Example 1 was carried out to prepare a colored resin composition. The obtained colored resin composition had a favorable initial transmittance of 51.0. In addition, weather resistance was evaluated with a backlight luminance of 10000 cd/m², and the result showed that the colored resin composition had a favorable transmittance retention ratio of 84%. Further, the photosensitivity was evaluated, and the result showed that the colored resin composition had favorable property with the necessary exposure amount being 40 mJ/cm². This indicates that an initiator having a nitrocarbazole portion has both an effect as a quencher and an effect as a photopolymerization initiator.

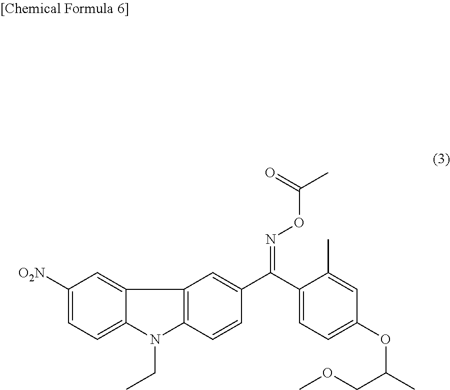 [SMILES: CCn1c2ccc(/C(=N/OC(C)=O)c3ccc(OC(C)COC)cc3C)cc2c2cc([N+](=O)[O-])ccc21]

### Comparative Example 1

Except that a quencher was not added, exactly the same procedure as in Example 1 was carried out to prepare a colored resin composition. The obtained colored resin composition had a favorable initial transmittance of 51.0, but had an insufficient transmittance retention ratio of 74% with a backlight luminance of 10000 cd/m² after evaluation of weather resistance.

Comparison between Comparative Example 1 and Example 2 indicates that 9-ethyl-3-nitrocarbazole exhibited an effect as a quencher.

### Comparative Example 2

Except that 9-ethyl-3-nitrocarbazole was replaced by a hindered amine light stabilizer (“TINUVIN (registered trademark) 770 DF” manufactured by BASF SE), exactly the same procedure as in Example 1 was carried out to prepare a colored resin composition. The obtained colored resin composition had a favorable initial transmittance of 51.0, but had an insufficient luminance retention ratio of 77% with a backlight luminance of 10000 cd/m² after evaluation of weather resistance although the luminance retention ratio was slightly improved as compared to Comparative Example 1.

### Comparative Example 3

Except that 9-ethyl-3-nitrocarbazole was replaced by a carbazole of the following formula, exactly the same procedure as in Example 1 was carried out to prepare a colored resin composition. The obtained colored resin composition had a favorable initial transmittance of 51.0, but had an insufficient transmittance retention ratio of 74% after evaluation of weather resistance. That is, a carbazole which does not contain a nitro group does not exhibit an effect as a quencher.

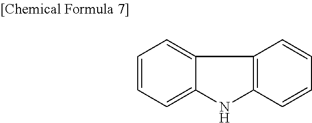 [SMILES: c1ccc2c(c1)[nH]c1ccccc12]

### Comparative Example 4

Except that 9-ethyl-3-nitrocarbazole as a quencher in Example 1 was replaced by a nitro group-free carbazole-based initiator of the following formula (“OXE02” manufactured by BASF SE), exactly the same procedure as in Example 1 was carried out to prepare a colored resin composition. The obtained colored resin composition had a favorable initial transmittance of 51.0. In addition, weather resistance was evaluated with a backlight luminance of 10000 cd/m², and the result showed that the colored resin composition had an insufficient transmittance retention ratio of 74%. This indicates that a nitro group-free carbazole initiator does not have an effect as a quencher.

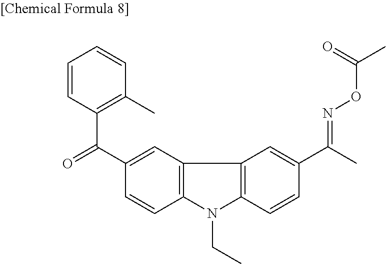 [SMILES: CCn1c2ccc(C(=O)c3ccccc3C)cc2c2cc(/C(C)=N/OC(C)=O)ccc21]

### Comparative Example 5

Except that 9-ethyl-3-nitrocarbazole as a quencher in Example 1 was replaced by a nitro group-free carbazole-based initiator of the following formula (“N1919” manufactured by ADEKA CORPORATION), exactly the same procedure as in Example 1 was carried out to prepare a colored resin composition. The obtained colored resin composition had a favorable initial transmittance of 51.0. In addition, the colored resin composition had an insufficient transmittance retention ratio of 74% with a backlight luminance of 10000 cd/m². This indicates that a nitro group-free carbazole initiator does not have an effect as a quencher.

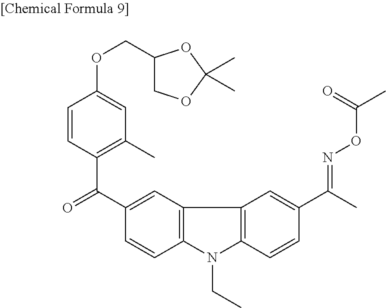 [SMILES: CCn1c2ccc(C(=O)c3ccc(OCC4COC(C)(C)O4)cc3C)cc2c2cc(/C(C)=N/OC(C)=O)ccc21]

### Example 3

Except that in place of Pigment Green 58 in Example 2, Pigment Green 59 also composed of polyhalogenated zinc phthalocyanine was used, and the ratio of Pigment Green 59 and Pigment Yellow 138 was set as shown in Table 2, exactly the same procedure as in Example 2 was carried out to prepare a colored resin composition. The colored resin composition had a favorable initial transmittance of 50.5. In addition, the transmittance retention ratio was evaluated with a backlight luminance of 10000 cd/m², and the result showed that the colored resin composition had a practically sufficient transmittance retention ratio of 89%. This indicates that a combination of a polyhalogenated zinc phthalocyanine, Pigment Yellow 138 and a compound of the general formula (1) has an extremely favorable initial transmittance and a favorable transmittance retention ratio.

### Examples 4 and 5

Except that in place of Pigment Yellow 138 in Example 2, Pigment Yellow 185 was used, and the blending ratio was set as shown in Table 2, exactly the same procedure as in Example 2 was carried out to prepare a colored resin composition, and evaluation was performed with a backlight luminance of 10000 cd/m² (Example 4). In addition, except that in place of Pigment Yellow 138 in Example 3, Pigment Yellow 185 was used, and the blending ratio was set as shown in Table 2, exactly the same procedure as in Example 3 was carried out to prepare a colored resin composition, and evaluation was performed (Example 5). The colored resin composition had an extremely favorable initial transmittance (52.0 in Example 4 and 51.4 in Example 5). In addition, the transmittance retention ratio was evaluated with a backlight luminance of 10000 cd/m², and the result showed that the colored resin composition had an extremely favorable transmittance retention ratio (93% in Examples 4 and 5). This indicates that a combination of a polyhalogenated zinc phthalocyanine, Pigment Yellow 185 and a compound of the general formula (1) has an extremely favorable initial transmittance and transmittance retention ratio.

### Examples 6, 7 and 8

Except that Pigment Yellow 150 was further added in Example 2, and the blending ratio was set as shown in Table 2, exactly the same procedure as in Example 2 was carried out to prepare a colored resin composition, and evaluation was performed. As the ratio of Pigment Yellow 138 decreased, the initial transmittance tended to decrease (50.5 in Example 6, 50.0 in Example 7 and 49.5 in Example 8), but the initial transmittance fell within a practically acceptable range. In addition, the transmittance retention ratio was evaluated with a backlight luminance of 10000 cd/m², and the result showed that the colored resin composition had an extremely favorable transmittance retention ratio (90% in Example 6, 92% in Example 7 and 96% in Example 8). Further, photosensitive property was evaluated, and the result showed that the colored resin composition in each of Examples 6, 7, and 8 had a sufficient sensitivity of 40 mJ/cm².

In addition, comparison between the initial transmittance and the total content of a polyhalogenated zinc phthalocyanine and C.I. Pigment Yellow 138 where the total of C.I. Pigment Yellow 138, a binder resin, a reactive monomer and a dispersant is 100% by mass indicates that the initial transmittance is high when the total content of a polyhalogenated zinc phthalocyanine and C.I. Pigment Yellow 138 is 43% by mass or more.

### Examples 9 and 10

Except that in addition to a quencher of the general formula (3), a chain transfer agent (KARENZ (registered trademark) MT PE-1 (pentaerythritol tetrakis(3-mercaptopropionate) manufactured by Showa Denko K.K. in Example 9), KARENZ (registered trademark) MT NR-1 (1,3,5 tris(3-mercaptobutyloxyethyl)-1,3,5-triazine-2,4,6(1H,3H,5H)-trione) manufactured by Showa Denko K.K. in Example 10) was added, exactly the same procedure as in Example 2 was carried out to prepare a colored resin composition, and evaluation was performed. The colored resin composition in each of Examples 9 and 10 had a favorable initial transmittance and transmittance retention ratio with a backlight luminance of 10000 cd/m², and an extremely high and favorable sensitivity. This indicates that the chain transfer agent can improve only the sensitivity without impairing other properties.

### Example 11

Except that in addition to a quencher of the general formula (3), a sensitizer (DETX-S (2,4-diethylthioxanthene-9-one) manufactured by Nippon Kayaku Co., Ltd.) was added, exactly the same procedure as in Example 2 was carried out to prepare a colored resin composition, and evaluation was performed. The colored resin composition had a favorable initial transmittance and transmittance retention ratio with a backlight luminance of 10000 cd/m², and an extremely high and favorable sensitivity. This indicates that the sensitizer can improve only the sensitivity without impairing other properties.

### Example 12

Except that the colorant was as shown in Table 2, exactly the same procedure as in Example 2 was carried out to prepare a colored resin composition, and evaluation was performed. The transmittance retention ratio was evaluated with a backlight luminance of 10000 cd/m², and the result showed that the colored resin composition had a sufficient transmittance retention ratio of 100%.

### Comparative Example 6

Except that the backlight luminance was 20000 cd/m², exactly the same procedure as in Comparative Example 1 was carried out to prepare a colored resin composition, and evaluation was performed. The luminance retention ratio further decreased to 70% as the backlight luminance increased.

### Example 13

Except that the backlight luminance was 20000 cd/m², exactly the same procedure as in Example 2 was carried out to prepare a colored resin composition, and evaluation was performed. The luminance retention ratio slightly decreased to 80%, but it was a value sufficiently acceptable in practical use.

### Example 14

Except that the backlight luminance was 20000 cd/m², exactly the same procedure as in Example 12 was carried out to prepare a colored resin composition, and evaluation was performed. The luminance retention ratio slightly decreased, but it was a very favorable value.

### Comparative Examples 7 and 8

Except that initiator was changed to a nitro group-free initiator (OXE02 in Comparative Example 7 and N1919 in Comparative Example 8), exactly the same procedure as in Example 14 was carried out to prepare a colored resin composition. The luminance retention ratio considerably decreased, and it was an insufficient value.

### Reference Examples 1 to 5

Reference Examples 1 to 5 were carried out exactly in the same manner as in Examples 14, 2 and 4 and Comparative Examples 7 and 8 except that the backlight luminance was 5000 cd/m². Since the backlight luminance was low, the luminance retention ratio was high. This indicates that when the backlight luminance is low, the luminance hardly decreases as a matter of course.

TABLE 1

| | | | | | | Alkali- | | | Chain | | |
|---|---|---|---|---|---|---|---|---|---|---|---|
| | | | | | | soluble | Reactive | | transfer | Sensi- | |
| | Dispersion liquid | | | | | resin | monomer | Quencher | agent | tizer | Solvent |
| Example 1 | D-1 | D-2 | | | | Cyclomer | DPHA | 9-ethyl-3-nitrocarbazole | | | PMA |
| | 36.84 | 24.56 | | | | 1.51 | 4.59 | 0.29 | | | 32.21 |
| Example 2 | D-1 | D-2 | | | | Cyclomer | DPHA | General formula (3) | | | PMA |
| | 36.84 | 24.56 | | | | 1.51 | 4.59 | 0.29 | | | 32.21 |
| Comparative | D-1 | D-2 | | | | Cyclomer | DPHA | | | | PMA |
| Example 1 | 36.84 | 24.56 | | | | 1.51 | 4.59 | | | | 32.50 |
| Comparative | D-1 | D-2 | | | | Cyclomer | DPHA | TINUVIN770DF | | | PMA |
| Example 2 | 36.84 | 24.56 | | | | 1.51 | 4.59 | 0.29 | | | 32.21 |
| Comparative | D-1 | D-2 | | | | Cyclomer | DPHA | Carbazole | | | PMA |
| Example 3 | 36.84 | 24.56 | | | | 1.51 | 4.59 | 0.29 | | | 32.21 |
| Comparative | D-1 | D-2 | | | | Cyclomer | DPHA | OX02 | | | PMA |
| Example 4 | 36.84 | 24.56 | | | | 1.51 | 4.59 | 0.29 | | | 32.21 |
| Comparative | D-1 | D-2 | | | | Cyclomer | DPHA | N1919 | | | PMA |
| Example 5 | 36.84 | 24.56 | | | | 1.51 | 4.59 | 0.29 | | | 32.21 |
| Example 3 | | D-2 | | D-4 | | Cyclomer | DPHA | General formula (3) | | | DPMA |
| | | 46.05 | | 15.35 | | 1.51 | 4.59 | 0.29 | | | 32.21 |
| Example 4 | D-1 | | | | D-5 | Cyclomer | DPHA | General formula (3) | | | DPMA |
| | 35.42 | | | | 3.08 | 9.47 | 7.99 | 0.50 | | | 43.53 |
| Example 5 | | | | D-4 | D-5 | Cyclomer | DPHA | General formula (3) | | | DPMA |
| | | | | 19.26 | 6.77 | 14.29 | 10.14 | 0.25 | | | 49.29 |
| Example 6 | D-1 | D-2 | D-3 | | | Cyclomer | DPHA | General formula (3) | | | DPMA |
| | 36.77 | 18.38 | 3.21 | | | 2.57 | 5.04 | 0.32 | | | 33.71 |
| Example 7 | D-1 | D-2 | D-3 | | | Cyclomer | DPHA | General formula (3) | | | DPMA |
| | 36.68 | 12.23 | 6.42 | | | 3.63 | 5.49 | 0.34 | | | 35.21 |
| Example 8 | D-1 | D-2 | D-3 | | | Cyclomer | DPHA | General formula (3) | | | DPMA |
| | 36.56 | 6.12 | 9.62 | | | 4.68 | 5.94 | 0.37 | | | 36.71 |
| Example 9 | D-1 | D-2 | | | | Cyclomer | DPHA | General formula (3) | PE-1 | | DPMA |
| | 36.73 | 24.48 | | | | 1.51 | 4.58 | 0.29 | 0.06 | | 32.36 |
| Example 10 | D-1 | D-2 | | | | Cyclomer | DPHA | General formula (3) | ME-1 | | DPMA |
| | 36.73 | 24.48 | | | | 1.51 | 4.58 | 0.29 | 0.06 | | 32.36 |
| Example 11 | D-1 | D-2 | | | | Cyclomer | DPHA | General formula (3) | | DETX | DPMA |
| | 36.73 | 24.48 | | | | 1.51 | 4.58 | 0.29 | | 0.06 | 32.36 |
| Example 12 | D-1 | | D-3 | | | Cyclomer | DPHA | General formula (3) | | | DPMA |
| | 36.47 | | 12.81 | | | 5.73 | 6.39 | 0.40 | | | 38.20 |
| Comparative | D-1 | D-2 | | | | Cyclomer | DPHA | | | | PMA |
| Example 6 | 36.84 | 24.56 | | | | 1.51 | 4.59 | | | | 32.50 |
| Example 13 | D-1 | D-2 | | | | Cyclomer | DPHA | General formula (3) | | | PMA |
| | 36.84 | 29.56 | | | | 1.51 | 4.59 | 0.29 | | | 32.21 |
| Example 14 | D-1 | | D-3 | | | Cyclomer | DPHA | General formula (3) | | | DPMA |
| | 36.47 | | 12.81 | | | 5.73 | 6.39 | 0.40 | | | 38.20 |
| Comparative | D-1 | | D-3 | | | Cyclomer | DPHA | OX02 | | | DPMA |
| Example 7 | 36.47 | | 12.81 | | | 5.73 | 6.39 | 0.40 | | | 38.20 |
| Comparative | D-1 | | D-3 | | | Cyclomer | DPHA | N1919 | | | DPMA |
| Example 8 | 36.47 | | 12.81 | | | 5.73 | 6.39 | 0.40 | | | 38.20 |

TABLE 2

| | | | | | | Y 138, | | | |
|---|---|---|---|---|---|---|---|---|---|
| | | | | | | Y 185/ | | Colorant | Green |
| | Content of colorant (% by mass) | | | | | yellow | | concentra- | pigment, |
| | G58 | G59 | Y138 | Y185 | Y150 | pigment | Quencher | tion | Y 138/resin |
| Example 1 | 60 | 0 | 40 | 0 | 0 | 100% | 9-ethyl-3-nitrocarbazole | 50.9% | 51% |
| Example 2 | 60 | 0 | 40 | 0 | 0 | 100% | General formula (3) | 50.9% | 51% |
| Comparative | 60 | 0 | 40 | 0 | 0 | 100% | None | 50.9% | 51% |
| Example 1 | | | | | | | | | |
| Comparative | 60 | 0 | 40 | 0 | 0 | 100% | TINUVIN 770DF | 50.9% | 51% |
| Example 2 | | | | | | | | | |
| Comparative | 60 | 0 | 40 | 0 | 0 | 100% | Carbazole | 50.9% | 51% |
| Example 3 | | | | | | | | | |
| Comparative | 60 | 0 | 40 | 0 | 0 | 100% | OXE02 | 50.9% | 51% |
| Example 4 | | | | | | | | | |
| Comparative | 60 | 0 | 40 | 0 | 0 | 100% | N1919 | 50.9% | 51% |
| Example 5 | | | | | | | | | |
| Example 3 | 0 | 25 | 75 | 0 | 0 | 100% | General formula (3) | 50.9% | 51% |
| Example 4 | 92 | 0 | 0 | 8 | 0 | 100% | General formula (3) | 29.1% | 27% |
| Example 5 | 0 | 74 | 0 | 26 | 0 | 100% | General formula (3) | 18.3% | 14% |
| Example 6 | 63 | 0 | 32 | 0 | 6 | 84% | General formula (3) | 47.8% | 45% |
| Example 7 | 66 | 0 | 22 | 0 | 11 | 67% | General formula (3) | 44.7% | 40% |
| Example 8 | 70 | 0 | 12 | 0 | 18 | 40% | General formula (3) | 41.7% | 34% |
| Example 9 | 60 | 0 | 40 | 0 | 0 | 100% | General formula (3) + PE 1 | 50.9% | 51% |
| Example 10 | 60 | 0 | 40 | 0 | 0 | 100% | General formula (3) + ME 1 | 50.9% | 51% |
| Example 11 | 60 | 0 | 40 | 0 | 0 | 100% | General formula (3) + DETX | 50.9% | 51% |
| Example 12 | 74 | 0 | 0 | 0 | 26 | 0% | General formula (3) | 38.8% | 29% |
| Comparative | 60 | 0 | 40 | 0 | 0 | 100% | None | 50.9% | 51% |
| Example 6 | | | | | | | | | |
| Example 13 | 60 | 0 | 40 | 0 | 0 | 100% | General formula (3) | 50.9% | 51% |
| Example 14 | 74 | 0 | 0 | 0 | 26 | 0% | General formula (3) | 38.8% | 29% |
| Comparative | 74 | 0 | 0 | 0 | 26 | 0% | OXE02 | 38.8% | 29% |
| Example 7 | | | | | | | | | |
| Comparative | 74 | 0 | 0 | 0 | 26 | 0% | N1919 | 38.8% | 29% |
| Example 8 | | | | | | | | | |
| Reference | 74 | 0 | 0 | 0 | 26 | 0% | General formula (3) | 38.8% | 29% |
| Example 1 | | | | | | | | | |
| Reference | 60 | 0 | 40 | 0 | 0 | 100% | General formula (3) | 50.9% | 51% |
| Example 2 | | | | | | | | | |
| Reference | 92 | 0 | 0 | 8 | 0 | 100% | General formula (3) | 29.1% | 27% |
| Example 3 | | | | | | | | | |
| Reference | 60 | 0 | 40 | 0 | 0 | 100% | OXE02 | 38.8% | 51% |
| Example 4 | | | | | | | | | |
| Reference | 60 | 0 | 40 | 0 | 0 | 100% | N1919 | 38.8% | 51% |
| Example 5 | | | | | | | | | |

TABLE 3

| | Thickness | | | | | | | |
|---|---|---|---|---|---|---|---|---|
| | of green | | | Backlight | Transmittance | | | |
| | pixels | Initial transmittance | | luminance | retention ratio | | Sensitivity | |
| | μm | Y | Evaluation | cd/m² | % | Evaluation | mJ/cm² | Evaluation |
| Example 1 | 2.68 | 51 | A | 10000 | 84 | B | Non-sensitive | Not evaluated |
| Example 2 | 2.68 | 51 | A | 10000 | 84 | B | 40 | B |
| Comparative | 2.55 | 51 | A | 10000 | 74 | C | Non-sensitive | Not evaluated |
| Example 1 | | | | | | | | |
| Comparative | 2.62 | 51 | A | 10000 | 77 | C | Non-sensitive | Not evaluated |
| Example 2 | | | | | | | | |
| Comparative | 2.65 | 51 | A | 10000 | 74 | C | Non-sensitive | Not evaluated |
| Example 3 | | | | | | | | |
| Comparative | 2.68 | 51 | A | 10000 | 74 | C | 40 | B |
| Example 4 | | | | | | | | |
| Comparative | 2.68 | 51 | A | 10000 | 74 | C | 40 | B |
| Example 5 | | | | | | | | |
| Example 3 | 2.66 | 50.5 | B | 10000 | 89 | B | 40 | B |
| Example 4 | 2.64 | 52.0 | A | 10000 | 93 | A | 40 | B |
| Example 5 | 2.60 | 51.4 | A | 10000 | 93 | A | 40 | B |
| Example 6 | 2.67 | 50.5 | B | 10000 | 90 | A | 40 | B |
| Example 7 | 2.65 | 50 | B | 10000 | 92 | A | 40 | B |
| Example 8 | 2.64 | 49.5 | B | 10000 | 96 | A | 40 | B |
| Example 9 | 2.68 | 51 | A | 10000 | 84 | B | 20 | A |
| Example 10 | 2.68 | 51 | A | 10000 | 84 | B | 30 | A |
| Example 11 | 2.69 | 51 | A | 10000 | 84 | B | 30 | A |
| Example 12 | 2.62 | 49 | C | 10000 | 100 | A | 40 | B |
| Comparative | 2.55 | 51 | A | 20000 | 70 | C | Non-sensitive | Not evaluated |
| Example 6 | | | | | | | | |
| Example 13 | 2.68 | 51 | A | 20000 | 80 | B | 40 | B |
| Example 14 | 2.62 | 49 | C | 20000 | 90 | A | 40 | B |
| Comparative | 2.52 | 49 | C | 20000 | 79 | C | 40 | B |
| Example 7 | | | | | | | | |
| Comparative | 2.52 | 49 | C | 20000 | 79 | C | 40 | B |
| Example 8 | | | | | | | | |
| Reference | 2.62 | 49 | C | 5000 | 100 | A | 40 | B |
| Example 1 | | | | | | | | |
| Reference | 2.68 | 51 | A | 5000 | 92 | A | 40 | B |
| Example 2 | | | | | | | | |
| Reference | 2.64 | 52.0 | A | 5000 | 97 | A | 40 | B |
| Example 3 | | | | | | | | |
| Reference | 2.68 | 51 | A | 5000 | 96 | A | 40 | B |
| Example 4 | | | | | | | | |
| Reference | 2.68 | 51 | A | 5000 | 96 | A | 40 | B |
| Example 5 | | | | | | | | |

In Table 3, the “Y 138, Y 185/yellow pigment” indicates the total content of C.I. Pigment Yellow 138 and Pigment Yellow 185 where the total content of the yellow pigments is 100% by mass. The “coloring agent concentration” indicates the total content of the polyhalogenated zinc phthalocyanine and the yellow pigment where the total content of the polyhalogenated zinc phthalocyanine, the yellow pigment, the binder resin, the reactive monomer and the dispersant is 100% by mass. The “green pigment, Y138/resin” indicates the total content of the polyhalogenated zinc phthalocyanine and C.I. Pigment Yellow 138 where the total content of the polyhalogenated zinc phthalocyanine, C.I. Pigment Yellow 138, the binder resin, the reactive monomer and the dispersant is 100% by mass.

The colored resin composition according to the present invention can be suitably used as a colored resin composition for forming pixels of a color filter substrate that is used in a liquid crystal display device.

1. A colored resin composition comprising a polyhalogenated zinc phthalocyanine, a yellow pigment, a binder resin, and a compound represented by the following general formula (1), the yellow pigment being a pigment selected from C.I. Pigment Yellow 138 and C.I. Pigment Yellow 185; 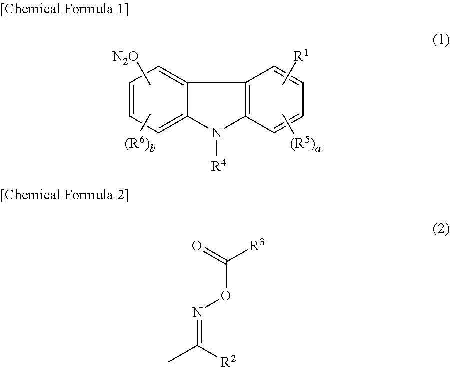
in the general formula (1), R¹ represents H, an alkyl group having 1 to 20 carbon atoms, an alkoxy group having 1 to 20 carbon atoms, an aryl group having 6 to 30 carbon atoms, an aryloxy group having 6 to 30 carbon atoms, an arylalkyl group having 7 to 30 carbon atoms, an arylalkyloxy group having 7 to 30 carbon atoms, a heterocyclic group having 2 to 20 carbon atoms, CN, a halogen atom or a group represented by the general formula (2);
R⁴ represents an alkyl group having 1 to 20 carbon atoms, an aryl group having 6 to 30 carbon atoms or an arylalkyl group having 7 to 30 carbon atoms, and R⁴ may form a ring with an adjacent benzene ring;
R⁵ and R⁶ each independently represent an alkyl group having 1 to 20 carbon atoms, an alkoxy group having 1 to 20 carbon atoms, an aryl group having 6 to 30 carbon atoms, an aryloxy group having 6 to 30 carbon atoms, an arylalkyl group having 7 to 30 carbon atoms, an arylalkyloxy group having 7 to 30 carbon atoms, a heterocyclic group having 2 to 20 carbon atoms, CN or a halogen atom, and a and b each independently represent 0 to 3;
R² represents an alkyl group having 1 to 20 carbon atoms, an aryl group having 6 to 30 carbon atoms, an arylalkyl group having 7 to 30 carbon atoms, a heterocyclic group having 2 to 20 carbon atoms or CN, and
at least some of hydrogen atoms of the alkyl group, the aryl group, the arylalkyl group and the heterocyclic group may be substituted with OR²¹, COR²¹, SR²¹, NR²²R²³, —NCOR²²—OCOR²³, CN, a halogen atom, —CR²¹═CR²²R²³ or —CO—CR²¹═CR²²R²³;
R²¹, R²² and R²³ each independently represent a hydrogen atom, an alkyl group having 1 to 20 carbon atoms, an alkenyl group having 1 to 20 carbon atoms, an aryl group having 6 to 30 carbon atoms, an arylalkyl group having 7 to 30 carbon atoms, or a heterocyclic group of 2 to 20 carbon atoms;
R³ represents an alkyl group having 1 to 20 carbon atoms, an alkoxy group having 1 to 20 carbon atoms, an aryl group having 6 to 30 carbon atoms, an aryloxy group having 6 to 30 carbon atoms, an arylalkyl group having 7 to 30 carbon atoms, an arylalkyl group having 7 to 30 carbon atoms, an arylalkyloxy group having 7 to 30 carbon atoms, or a heterocyclic group having 2 to 20 carbon atoms, and at least some of hydrogen atoms of these groups may be further substituted with, a halogen atom; and
in the above description, the alkyl group may be linear, branched or cyclic, and the alkyl group may contain 1 to 5 bonds selected from unsaturated bonds, ether bonds, thioether bonds, ester bonds, thioester bonds, amide bonds and urethane bonds in the alkyl chain.

2. The colored resin composition according to claim 1, wherein the yellow pigment contains C.I. Pigment Yellow 138, the colored resin composition further includes a reactive monomer and a dispersant, and the total content of the polyhalogenated zinc phthalocyanine and C.I. Pigment Yellow 138 is 43 to 55% by mass where the total content of the polyhalogenated zinc phthalocyanine, C.I. Pigment Yellow 138, the binder resin, the reactive monomer and the dispersant is 100% by mass.

3. The colored resin composition according to claim 1, wherein the compound represented by the general formula (1) is a compound represented by the following chemical formula (3):

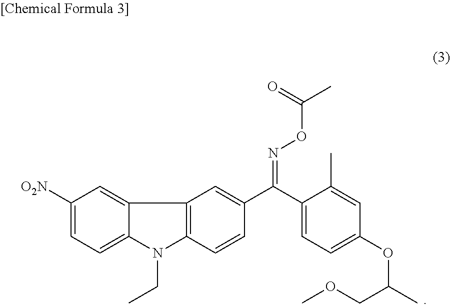

4. The colored resin composition according to claim 1, wherein the polyhalogenated zinc phthalocyanine is at least one selected from C.I. Pigment Green 58 and C.I. Pigment Green 59.

5. The colored resin composition according to claim 1, wherein the colored resin composition further includes C.I. Pigment Yellow 150, and the total content of C.I. Pigment Yellow 138 and Pigment Yellow 185 is 20 to 80% by mass where the total content of the yellow pigments is 100% by mass.

6. The colored resin composition according to claim 1, further comprising a chain transfer agent.

7. The colored resin composition according to claim 1, further comprising a sensitizer.

8. A color filter substrate having pixels formed using the colored resin composition according to claim 1.

9. A liquid crystal display device in which a color filter substrate and a counter substrate are bonded to each other, a liquid crystal compound is packed between both the substrates, and a backlight is provided, the color filter substrate having pixels containing a polyhalogenated zinc phthalocyanine, a yellow pigment, a binder resin and a compound represented by the following general formula (1), the yellow pigment being at least one selected from the group consisting of C.I. Pigment Yellow 150, C.I. Pigment Yellow 138 and C.I. Pigment Yellow 185, the backlight having a luminance of 8000 to 100000 cd/m²; 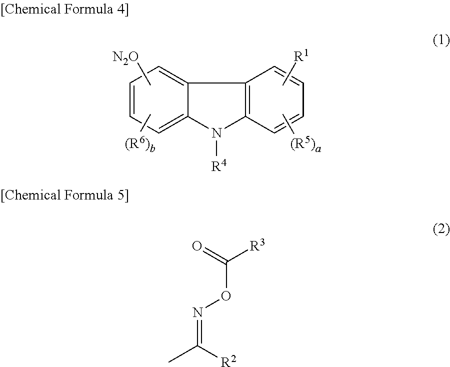
in the general formula (1), R¹ represents H, an alkyl group having 1 to 20 carbon atoms, an alkoxy group having 1 to 20 carbon atoms, an aryl group having 6 to 30 carbon atoms, an aryloxy group having 6 to 30 carbon atoms, an arylalkyl group having 7 to 30 carbon atoms, an arylalkyloxy group having 7 to 30 carbon atoms, a heterocyclic group having 2 to 20 carbon atoms, CN, a halogen atom or a group represented by the general formula (2);
R⁴ represents an alkyl group having 1 to 20 carbon atoms, an aryl group having 6 to 30 carbon atoms or an arylalkyl group having 7 to 30 carbon atoms, and R⁴ may form a ring with an adjacent benzene ring;
R⁵ and R⁶ each independently represent an alkyl group having 1 to 20 carbon atoms, an alkoxy group having 1 to 20 carbon atoms, an aryl group having 6 to 30 carbon atoms, an aryloxy group having 6 to 30 carbon atoms, an arylalkyl group having 7 to 30 carbon atoms, an arylalkyloxy group having 7 to 30 carbon atoms, a heterocyclic group having 2 to 20 carbon atoms, CN or a halogen atom, and a and b each independently represent 0 to 3;
R² represents an alkyl group having 1 to 20 carbon atoms, an aryl group having 6 to 30 carbon atoms, an arylalkyl group having 7 to 30 carbon atoms, a heterocyclic group having 2 to 20 carbon atoms or CN, and
at least some of hydrogen atoms of the alkyl group, the aryl group, the arylalkyl group and the heterocyclic group may be substituted with OR²¹, COR²¹, SR²¹, NR²²R²³, —NCOR²²—OCOR²³, CN, a halogen atom, —CR²¹═CR²²R²³ or —CO—CR²¹═CR²²R²³;
R²¹, R²² and R²³ each independently represent a hydrogen atom, an alkyl group having 1 to 20 carbon atoms, an alkenyl group having 1 to 20 carbon atoms, an aryl group having 6 to 30 carbon atoms, an arylalkyl group having 7 to 30 carbon atoms, or a heterocyclic group of 2 to 20 carbon atoms;
R³ represents an alkyl group having 1 to 20 carbon atoms, an alkoxy group having 1 to 20 carbon atoms, an aryl group having 6 to 30 carbon atoms, an aryloxy group having 6 to 30 carbon atoms, an arylalkyl group having 7 to 30 carbon atoms, an arylalkyl group having 7 to 30 carbon atoms, an arylalkyloxy group having 7 to 30 carbon atoms, or a heterocyclic group having 2 to 20 carbon atoms, and at least some of hydrogen atoms of these groups may be further substituted with a halogen atom; and
in the above description, the alkyl group may be linear, branched or cyclic, and the alkyl group may contain 1 to 5 bonds selected from unsaturated bonds, ether bonds, thioether bonds, ester bonds, thioester bonds, amide bonds and urethane bonds in the alkyl chain.

10. The display device according to claim 9, wherein the compound represented by the general formula (1) is a compound represented by the following chemical formula (3):

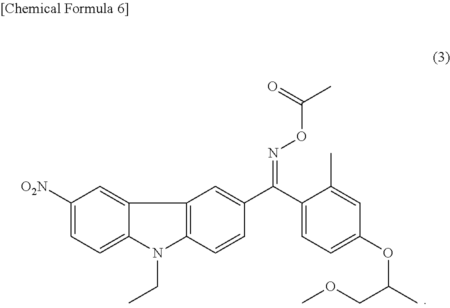

11. The display device according to claim 9, wherein the polyhalogenated zinc phthalocyanine is at least one selected from C.I. Pigment Green 58 and C.I. Pigment Green 59.

12. The display device according to claim 9, wherein the total content of C.I. Pigment Yellow 138 and Pigment Yellow 185 is 20 to 80% by mass where the total content of the yellow pigments is 100% by mass.

13. The display device according to claim 9, wherein the polyhalogenated zinc phthalocyanine is C.I. Pigment Green 59.

14. The display device according to claim 13, wherein the yellow pigment is Pigment Yellow 185.

15. The display device according to claim 9, wherein the content of the polyhalogenated zinc phthalocyanine is 72% by mass or more where the total content of the colorant of the colored resin composition is 100% by mass.
